(19) United States
(12) Patent Application Publication
(10) Pub. No.: US 2006/0264042 A1
(43) Pub. Date: Nov. 23, 2006

(54) Interconnect structure including a silicon oxycarbonitride layer

(75) Inventors: Laura M. Matz, Murphy, TX (US); Ting Y. Tsui, Garland, TX (US); Robert Kraft, Plano, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/134,698

(22) Filed: May 20, 2005

(51) Int. Cl. H01L 21/44

(52) U.S. Cl. 438/672

(57) ABSTRACT

The present invention provides an interconnect structure, a method of manufacture therefore, and an integrated circuit including the same. In one embodiment of the present invention, the interconnect structure includes a conductive feature (150) located in or over a dielectric layer (140), and a silicon oxycarbonitride layer (160) located over the conductive feature (150).

### TECHNICAL FIELD OF THE INVENTION

The present invention is directed, in general, to a protective layer and, more specifically, to an interconnect structure including a silicon oxycarbonitride layer, a method of manufacture therefore, and an integrated circuit including the same.

### BACKGROUND OF THE INVENTION

The push to decrease the size of submicron multilevel metallized interconnections, such as lines, via, and trenches, and the desire to produce faster semiconductor devices, has resulted in a shift toward the use of copper for making electrical interconnections in ultra-large scale integration circuits. Copper interconnects, however, because of their oxidizing nature, often require a hermetic layer be formed thereover after each metallization level. The hermetic layer serves as a barrier for moisture or oxygen diffusion into the underlying copper layer during damascene processing.

There is currently a tradeoff in the industry that the hermetic layer be thick enough to provide the requisite amount of hermetic protection for the copper interconnects, but thin enough such that the effective dielectric constant (k-effective) of the hermetic layer remains small, and thus does not increase the capacitance and therefore RC delay. In the current technology nodes, such as the 90 nm nodes and 65 nm nodes, a single hermetic layer thickness is capable of accomplishing both the requisite amount of hermetic protection and the requisite k-effective. For example, for these nodes a 60 nm thick SiCN hermetic layer can still be used to provide both the requisite amount of hermetic protection and the required k-effective.

Unfortunately, as the next generation technology nodes are introduced, such as the 45 nm node, it does not appear that a single hermetic layer thickness will accomplish both the requisite amount of hermetic protection and the decreasing k-effective requirement. When this occurs, the industry will be forced to decide whether to accept limited hermeticity protection in lieu of decreased k-effective values, or vice versa. Neither scenario is appealing to the industry.

Accordingly, what is needed in the art is a new hermetic layer or process for manufacture therefore, that would accommodate both the requisite amount of hermetic protection and the decreasing k-effective requirement for future nodes.

### SUMMARY OF THE INVENTION

To address the above-discussed deficiencies of the prior art, the present invention provides an interconnect structure, a method of manufacture therefore, and an integrated circuit including the same. In one embodiment of the present invention, the interconnect structure includes a conductive feature located in or over a dielectric layer, and a silicon oxycarbonitride layer located over the conductive feature. The method for manufacturing the integrated circuit, in another embodiment, includes providing and forming the aforementioned features.

As indicated above, another embodiment of the present invention is an integrated circuit. The integrated circuit may include: (1) transistor devices located over a substrate, (2) a dielectric layer located over the transistor devices, (3) a conductive feature located in or over the dielectric layer, and (4) a silicon oxycarbonitride layer located over the conductive feature.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGURES. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a cross-sectional view of one embodiment of an interconnect structure manufactured in accordance with the principles of the present invention;

FIG. 2 illustrates a cross-sectional view of an interconnect structure at an initial stage of manufacture;

FIG. 3 illustrates a cross-sectional view of the partially completed interconnect structure illustrated in FIG. 2 after forming an opening in the dielectric layer using an opening in a photoresist layer;

FIG. 4 illustrates a cross-sectional view of the partially completed interconnect structure illustrated in FIG. 3 after removing the photoresist layer and forming a conventional barrier/adhesion layer and blanket layer of conductive material over the dielectric layer and within the opening;

FIG. 5 illustrates a cross-sectional view of the partially completed interconnect structure illustrated in FIG. 4 after conventionally polishing the blanket layer of conductive material to form a second conductive feature;

FIG. 6 illustrates a cross-sectional view of the partially completed integrated circuit illustrated in FIG. 5 after forming an optional intermediate layer over the dielectric layer and the conductive plug;

FIG. 7 illustrates a cross-sectional view of the partially completed integrated circuit illustrated in FIG. 6 after forming a silicon oxycarbonitride layer over the conductive plug; and

FIG. 8 illustrates a cross-sectional view of an integrated circuit manufactured in accordance with the principles of the present invention.

### DETAILED DESCRIPTION

The present invention is based, at least in part, on the recognition that the inclusion of nitrogen into certain conventional layers will allow for a novel hermetic layer that is capable of balancing the tradeoff between effective dielectric constant (k-effective) and hermeticity, which are both traditionally inversely related to the thickness of the hermetic layer. The present invention specifically recognizes that nitrogen might be added to a silicon oxycarbide layer, in various amounts, to result in a silicon oxycarbonitride layer that provides similar, if not improved, heremeticity with a much thinner layer. Accordingly, the silicon oxycarbonitride layer would have the desired k-effective because of its reduced thickness, but would also have the requisite hermeticity required to protect the interconnect structure from external environments.

A hermetic layer, as used herein, is any layer that may impede the diffusion of moisture or oxygen within a stack of layers. For instance, in a semiconductor device, the hermetic layer may be placed in such a position as to impede the diffusion of moisture or oxygen from an interlevel dielectric layer to an underlying copper layer, thereby inhibiting copper oxidation. The hermeticity of a given hermetic layer is a measurement of the ability of the hermetic layer to impede the diffusion of moisture or oxygen over time. One method for measuring a hermetic layer's hermeticity is to place the hermetic layer over a tensile dielectric material (e.g., TEOS or OSG) and measure the tensile dielectric material's stress as a function of time. As moisture or oxygen diffuses into the hermetic layer the diffusion will show up as stress change in the dielectric layer. This is one appropriate measurement technique of a material's hermeticity. Other known measurement techniques may also be used to measure a given hermetic layer's hermeticity.

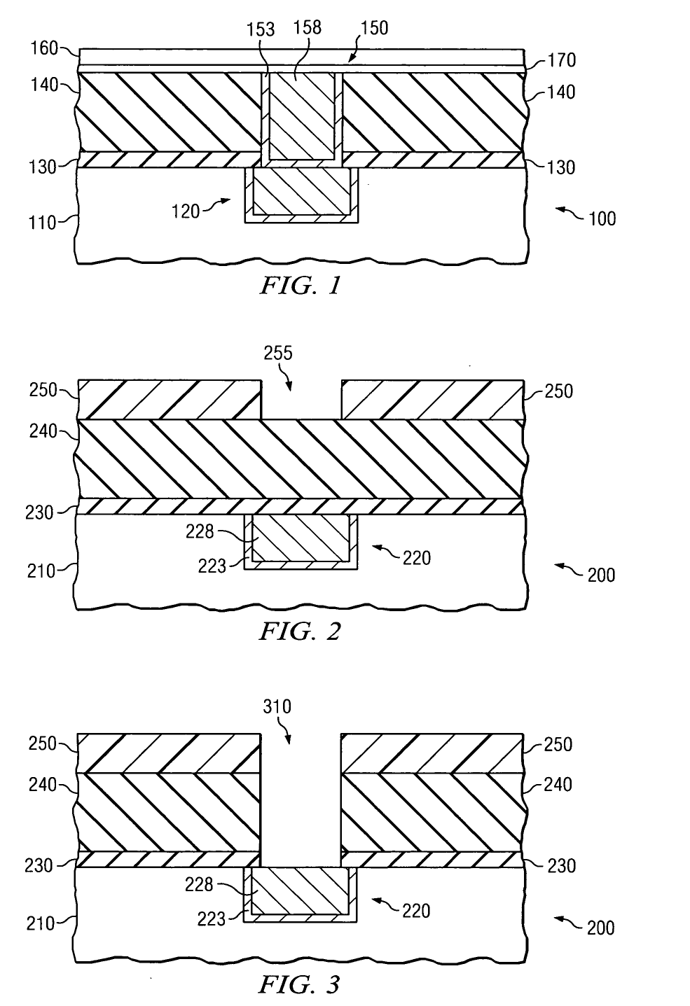

Turning initially to FIG. 1, illustrated is a cross-sectional view of one embodiment of an interconnect structure 100 manufactured in accordance with the principles of the present invention. The interconnect structure 100 illustrated in FIG. 1 initially includes a substrate 110 having a first conductive feature 120 therein or thereover. As will be detailed further below, both the substrate 110 and the first conductive feature 120 are conventional features capable of comprising a number of different materials and configurations without departing from the scope of the present invention.

Positioned over the substrate 110 and/or the first conductive feature 120, in the embodiment of FIG. 1, is a dielectric barrier layer 130. The dielectric barrier layer 130 may comprise any suitable material consistent with the present invention. In one embodiment, the dielectric barrier layer 130 comprises a silicon nitride layer, a silicon carbide layer, a silicon carbonitride layer, or another similar material. In another embodiment, however, the dielectric barrier layer 130 comprises a similar material as the silicon oxycarbonitride layer 160 discussed in more detail below.

Positioned over the dielectric barrier layer 130 may be a dielectric layer 140. The dielectric layer 140, in one exemplary embodiment, comprises a low dielectric constant (k) layer having an opening formed therein. While not limited to such, the dielectric layer 140 might comprise an organo-silicate glass (OSG) dielectric layer having a thickness ranging from about 50 nm to about 500 nm.

Located over the dielectric layer 140, and in this embodiment within the opening in the dielectric layer 140, is a second conductive feature 150. The second conductive feature 150 illustrated in FIG. 1 includes a barrier/adhesion layer portion 153 as well as a conductive plug 158. While the second conductive feature 150 illustrated in the embodiment of FIG. 1 is shown as via, those skilled in the relevant art understand that the second conductive feature 150 may comprise other conductive features, such as traces, runners, etc., without departing from the scope of the present invention.

Uniquely positioned over the second conductive feature 150 is a silicon oxycarbonitride layer 160. The silicon oxycarbonitride layer 160, by its very nature, must contain more than trace amounts of oxygen or nitrogen therein. As the silicon oxycarbonitride layer 160 contains more than trace amount of oxygen and nitrogen, the oxygen and nitrogen must be intentionally added to the silicon oxycarbonitride layer 160. As an example, in one embodiment of the present invention, the silicon oxycarbonitride layer 160 includes at least about 2 atomic weight percent oxygen. In the same or another embodiment of the present invention, the silicon oxycarbonitride layer 160 contains at least about 2 atomic weight percent nitrogen. In yet another embodiment of the present invention, the silicon oxycarbonitride layer 160 contains from about 15 atomic weight percent to about 30 atomic weight percent oxygen and/or from about 8 atomic weight percent to about 30 atomic weight percent nitrogen. In addition to the oxygen and nitrogen amounts just given, another embodiment of the present invention has the silicon oxycarbonitride layer 160 including from about 30 atomic weight percent to about 50 atomic weight percent silicon and/or from about 15 atomic weight percent to about 45 atomic weight percent carbon. While various ranges for the amounts of silicon, oxygen, carbon and nitrogen have been given above, it should be clear to the skilled artisan that other conceivable amounts outside of these ranges may exist; thus, the present invention should not be limited to such ranges.

The embodiment discussed in the paragraph above leads one to believe that the concentration profile of the nitrogen in the silicon oxycarbonitride layer 160 is flat. While this does represent one embodiment of the present invention, another embodiment exists wherein the nitrogen in the silicon oxycarbonitride layer 160 has a graded profile. Without limitation, this embodiment might include a nitrogen graded profile having a greater amount of nitrogen at a surface of the silicon oxycarbonitride layer 160 proximate the second conductive feature 150 than a surface of the silicon oxycarbonitride layer 160 distal the second conductive feature 150.

The inclusion of the nitrogen into the silicon oxycarbonitride layer 160 allows the thickness of the silicon oxycarbonitride layer 160 to be less than the thickness of traditional hermetic layers, while maintaining the same hermeticity properties. For instance, in one embodiment the thickness of the silicon oxycarbonitride layer 160 ranges from about 3 nm to about 100 nm, while continuing to provide the requisite hermeticity properties. In another exemplary embodiment of the present invention, however, the thickness of the silicon oxycarbonitride layer 160 ranges from about 5 nm to about 50 nm, while continuing to provide the requisite hermeticity properties.

The silicon oxycarbonitride layer 160, in accordance with the principles of the present invention, may have a plurality of different functions. For example, in one embodiment the silicon oxycarbonitride layer 160 functions as a hermetic layer. In another embodiment, however, the silicon oxycarbonitride layer 160 functions as an etch stop. In yet another embodiment, the silicon oxycarbonitride layer 160 functions as both a hermetic layer and an etch stop.

Optionally located between the silicon oxycarbonitride layer 160 and the second conductive feature 150 may be an intermediate layer 170. The intermediate layer 170, when used, may be designed to prevent the oxygen containing silicon oxycarbonitride layer 160 from contacting the second conductive feature 150. This is particularly advantageous when the second conductive feature 150 contains copper, which will readily oxidize in the presence of oxygen.

The intermediate layer 170 may comprise many different materials. For instance, the intermediate layer 170 may comprise a silicon nitride layer, a silicon carbide layer, a silicon carbonitride layer, etc. It should further be noted that the intermediate layer 170 need not be a thick layer, but could also be an atomic layer or thin film. Accordingly, the intermediate layer 170 could be formed by chemically treating the second conductive feature 150 prior to forming the silicon oxycarbonitride layer 160.

The silicon oxycarbonitride layer 160 provides a number of benefits not available when using conventional hermetic layers. For instance, the silicon oxycarbonitride layer 160 allows a thinner hermetic layer to be used, thereby decreasing the k-effective of the dielectric stack, while improving the hermeticity. Additionally, hermeticity tests show minimal water diffusion over time compared to current dielectric layers used for advanced technology node interconnects. Furthermore, it is believed that the silicon oxycarbonitride layer 160 may be added to the traditional process flows, and in one embodiment into the hermetic layer deposition tool, with minimal impact.

Turning now to FIGS. 2-7, illustrated are cross-sectional views of detailed manufacturing steps illustrating how one might manufacture an interconnect structure in accordance with the principles of the present invention. While the embodiments illustrated in FIGS. 2-6 are directed to a single damascene interconnect structure, the unique aspects of the present invention are also applicable to dual damascene interconnect structures.

FIG. 2 illustrates a cross-sectional view of an interconnect structure 200 at an initial stage of manufacture. The partially completed interconnect structure 200 illustrated in FIG. 2 initially includes a substrate 210 having a conductive feature 220 located there under. The substrate 210 may comprise a variety of different configurations and materials without departing from the inventive aspects of the present invention. For instance, in the embodiment of FIG. 2 the substrate 210 is a low dielectric constant (k) substrate. Suitable low dielectric constant (k) substrates include, among others, OSG, BPSG, PSG, TEOS, aerogel, xerogel, HSQ, MSQ or any other low dielectric constant materials. Nevertheless, the substrate 210 may comprise other non-low dielectric constant (k) substrates and remain within the scope of the present invention.

As previously mentioned, located over or in the substrate is a conductive feature 220. The conductive feature 220 may also comprise a number of different features while remaining within the scope of the present invention. In one aspect of the invention, the conductive feature 220 is a conductive trace, runner or trench traversing along at least a portion of an interlevel dielectric layer. In another aspect, however, the conductive feature 220 is a transistor device level feature, such as a gate electrode or source/drain contact region. Other conductive features 220 may also exist.

The conductive feature 220 illustrated in FIG. 2, however, happens to be a conductive trace, runner or trench. As illustrated, the conductive feature 220 includes a barrier/adhesion layer 223 and a conductive plug 228. The conductive plug 228 is preferably comprised of copper or copper-doped aluminum (preferably on the order of 0.5 to 2.5 wt % of copper in aluminum). Other copper containing conductive plugs 228, or for that matter other general conductive plugs, are within the scope of the present invention. The barrier/adhesion layer 223, among others, may comprise titanium, titanium nitride, a Ti/TiN stack, tantalum, tantalum nitride, or other barrier-like materials or mixtures of these materials that adhere well to copper, aluminum and/or the substrate 210.

Optionally located over the substrate 210 and the conductive feature 220 may be a dielectric barrier layer 230. The dielectric barrier layer 230, in accordance with the principles of the present invention, may comprise silicon nitride, silicon carbide, silicon carbonitride or other similar materials, for example. Various different compositions and configurations for the dielectric barrier layer 230 may, nonetheless, exist.

Positioned over the substrate 210 and the conductive feature 220 in the embodiment of FIG. 2 is a dielectric layer 240. In the embodiment of FIG. 2 the dielectric layer 240 is a low dielectric constant (k) dielectric layer. The low dielectric constant (k) dielectric layer, similar to the embodiment wherein the substrate 210 comprises a low dielectric constant (k) material, may comprise, among others, OSG, BPSG, PSG, TEOS, aerogel, xerogel, HSQ, MSQ or any other low dielectric constant materials. Other embodiments exist wherein the dielectric layer 240 does not comprise a low dielectric constant (k) material, such as TEOS.

Positioned over the dielectric layer 240 is a photoresist layer 250. The photoresist layer 250 illustrated in FIG. 2 comprises only a single layer; however, those skilled in the art understand that the photoresist layer 250 could comprise any number of layers while staying within the scope of the present invention. One such embodiment might be where the photoresist layer 250 comprises both a BARC portion and a photoresist portion. As illustrated in FIG. 2, the photoresist layer 250 has an opening 255 conventionally patterned therein. Those skilled in the art understand the process for forming and patterning the photoresist layer 250, thus no further detail is warranted.

Turning now to FIG. 3, illustrated is a cross-sectional view of the partially completed interconnect structure 200 illustrated in FIG. 2 after forming an opening 310 in the dielectric layer 240 using the opening 255 (FIG. 2) in the photoresist layer 250. Preferably, this is accomplished by subjecting the dielectric layer 240 to CF₄, CHF₃, or other fluorinated compound plasma environment. Nevertheless, any other known or hereafter discovered process could be used to form the opening 310. It should also be noted that certain embodiments may exist wherein a second process is used to remove the portion of the dielectric barrier layer 230 exposed by the dielectric layer 240 etch. In this embodiment, a conventional fluorine containing plasma etch could be used to remove the exposed portion of the dielectric barrier layer 230.

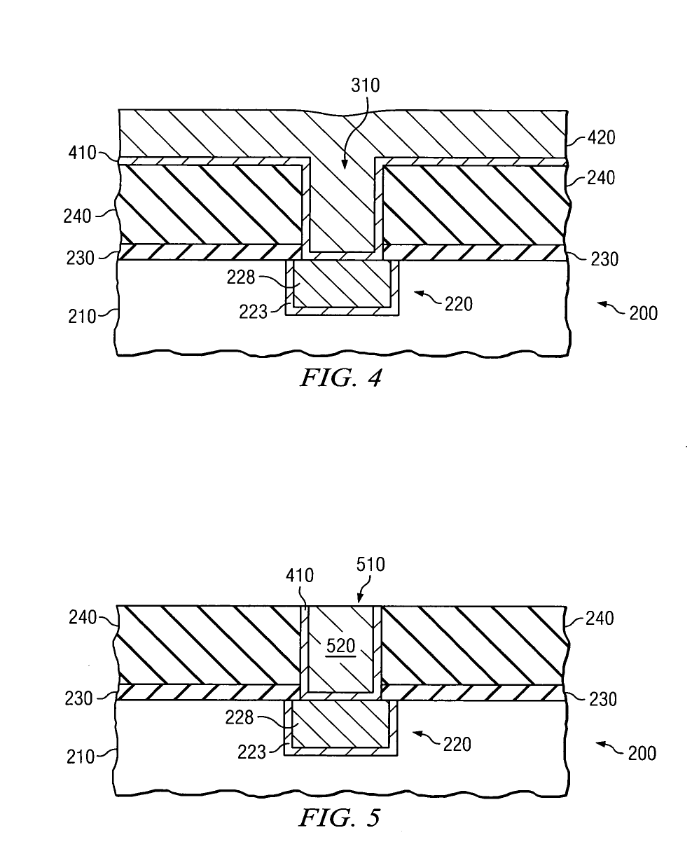

Turning now to FIG. 4, illustrated is a cross-sectional view of the partially completed interconnect structure 200 illustrated in FIG. 3 after removing the photoresist layer 250 (FIG. 3) and forming a conventional barrier/adhesion layer 410 and blanket layer of conductive material 420, both of which are over the dielectric layer 240 and within the opening 310. Those skilled in the art understand the conventional processes that might be used to remove the photoresist layer 250 (FIG. 3). Accordingly, no further detail will be given to describe such conventional processes.

The metal barrier/adhesion layer 410 may comprise similar types of materials as the barrier/adhesion layer 223, such as titanium, titanium nitride, a Ti/TiN stack, tantalum, tantalum nitride, or other barrier-like materials or mixtures of these materials that adhere well to copper, aluminum and/or the dielectric layer 240. Similarly, the blanket layer of conductive material 420 may comprise similar types of materials as the conductive plug 228. Therefore, in the embodiment of FIG. 4, the metal barrier/adhesion layer 410 comprises a tantalum/tantalum nitride stack and the blanket layer of conductive material 420 comprises copper or copper doped aluminum.

Turning now to FIG. 5, illustrated is a cross-sectional view of the partially completed interconnect structure 200 illustrated in FIG. 4 after conventionally polishing the blanket layer of conductive material 420 to form a second conductive feature 510. The second conductive feature 510, as those skilled in the art would expect, comprises the metal barrier/adhesion layer 410 and a polished conductive plug 520. The planarization is preferably accomplished by chemical-mechanical polishing (CMP) or a blanket etch-back process.

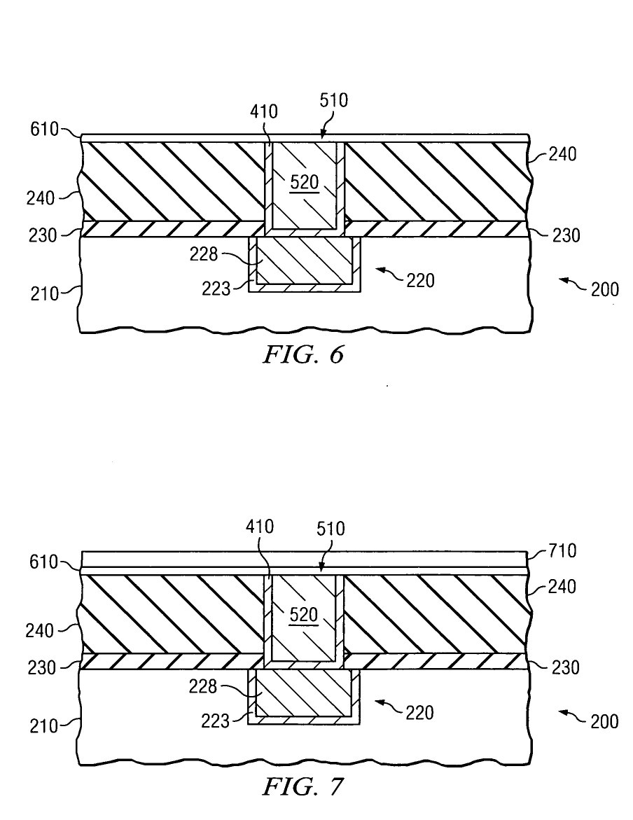

Turning now to FIG. 6, illustrated is a cross-sectional view of the partially completed integrated circuit 200 illustrated in FIG. 5 after forming an optional intermediate layer 610 over the dielectric layer 240 and the conductive plug 520. The intermediate layer 610 may comprise many different materials. For example, in one embodiment the intermediate layer comprises silicon nitride, silicon carbide, silicon carbonitride, or another similar material. In those embodiments wherein the intermediate layer 610 is used, it is generally important that the intermediate layer 610 not include substantial, if any, amounts of oxygen. In those embodiments wherein the intermediate layer 610 does not contain oxygen, the conductive plug 520 is not generally susceptible to oxidation.

The intermediate layer 610 may be formed using various different processes and to various different thicknesses. For instance, in one embodiment the intermediate layer is formed using a plasma enhanced chemical vapor deposition (PECVD) process to a thickness ranging from about 5 nm to about 50 nm. In an alternative embodiment, however, the intermediate layer 610 is formed using a chemical pretreatment applied to the conductive plug 520. In this embodiment, the intermediate layer 610 may only be atoms thick, and thus not be referred to as a layer at all. In conclusion, the intermediate layer 610 may be formed from any process, comprise any material, be any thickness, etc., as long as it accomplishes its purposes set-forth herein.

Turning now to FIG. 7, illustrated is a cross-sectional view of the partially completed integrated circuit 200 illustrated in FIG. 6 after forming a silicon oxycarbonitride layer 710 over the silicon oxycarbonitride layer 710. In those embodiments wherein the intermediate layer 610 does exist, the silicon oxycarbonitride layer 710 would be formed over the intermediate layer 610. As detailed in the paragraphs above, the silicon oxycarbonitride layer 710 may comprise different amounts of silicon, oxygen, carbon and nitrogen, and remain within the scope of the present invention.

The silicon oxycarbonitride layer 710 may be formed using various different techniques. Nevertheless, in one embodiment of the invention the silicon oxycarbonitride layer 710 is formed using a PECVD technique. For example, the silicon oxycarbonitride layer 710 could be formed using gasses such as ammonia, helium, trimethyl silane, carbon dioxide and hydrogen. When forming the silicon oxycarbonitride layer 710 using these gasses, the ammonia flow rate might range from about 100 sccm to about 2000 sccm, the helium flow rate might range from about 100 sccm to about 2000 sccm, the trimethyl silane flow rate might range from about 40 sccm to about 500 sccm, the carbon dioxide flow rate might range from about 100 sccm to about 2000 sccm, and the hydrogen flow rate might range from about 100 sccm to about 2000 sccm. Other flow rates could nevertheless also be used. The PECVD technique might also use a deposition power ranging from about 100 Watts to about 500 Watts, and a temperature ranging from about 300° C. to about 400° C., among others.

The silicon oxycarbonitride layer 710 layer illustrated in FIG. 7 contains substantially consistent amounts of nitrogen therethrough. However, other embodiments exists wherein the nitrogen in the silicon oxycarbonitride layer 710 is graded. For example, one exemplary embodiment exists wherein the nitrogen amount in the silicon oxycarbonitride layer 710 is greater at a surface of the silicon oxycarbonitride layer 710 proximate the conductive plug 520 than a surface of the silicon oxycarbonitride layer 710 distal the conductive plug 520. Another embodiment might also be used where the inverse is true. Those skilled in the art understand the process that might be used to form the graded nitrogen silicon oxycarbonitride layer 710, including using large flow rate of ammonia during the initial deposition stages of the silicon oxycarbonitride layer 710 and decreasing the flow rate of ammonia as the deposition process continues. Other processes might also be used.

After completing the silicon oxycarbonitride layer 710 layer the manufacturing of the interconnect structure 200 might continue in a conventional manner. For example, the manufacturing might continue in a manner sufficient to provide a device similar to the completed interconnect structure 100 illustrated in FIG. 1.

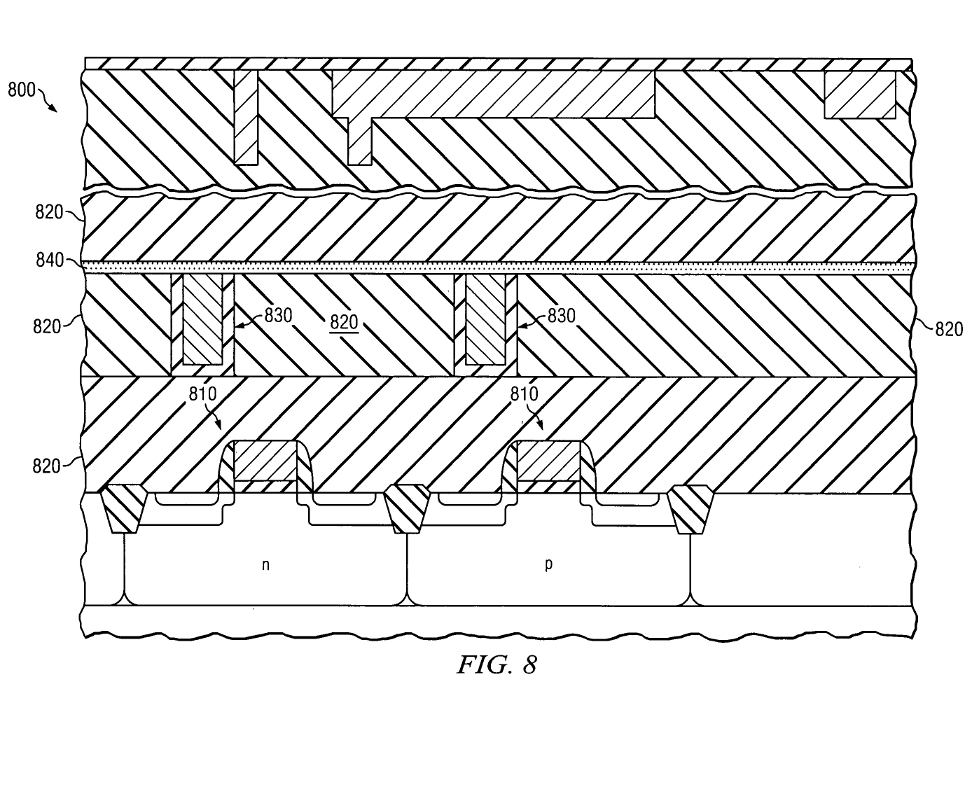

Referring now to FIG. 8, illustrated is an exemplary cross-sectional view of an integrated circuit (IC) 800 incorporating interconnect structures 830 constructed according to the principles of the present invention. The IC 800 may include devices, such as transistors used to form CMOS devices, BiCMOS devices, Bipolar devices, as well as capacitors or other types of devices. The IC 800 may further include passive devices, such as inductors or resistors, or it may also include optical devices or optoelectronic devices. Those skilled in the art are familiar with these various types of devices and their manufacture. In the particular embodiment illustrated in FIG. 8, the IC 800 includes transistor devices 810 having dielectric layers 820 located thereover. Additionally, interconnect structures 830 are located within the dielectric layers 820 to interconnect various devices, thus, forming the operational integrated circuit 800. As is illustrated, a silicon oxycarbonitride layer 840 forms at least a portion of the interconnect structures 830.

Although the present invention has been described in detail, those skilled in the art should understand that they can make various changes, substitutions and alterations herein without departing from the spirit and scope of the invention in its broadest form.

What is claimed is:

1. An interconnect structure, comprising;
a conductive feature located in or over a dielectric layer; and
a silicon oxycarbonitride layer located over the conductive feature.

2. The interconnect structure as recited in claim 1 wherein the silicon oxycarbonitride layer includes at least about 2 atomic weight percent oxygen.

3. The interconnect structure as recited in claim 1 wherein the silicon oxycarbonitride layer includes at least about 2 atomic weight percent nitrogen.

4. The interconnect structure as recited in claim 1 wherein the silicon oxycarbonitride layer includes from about 30 atomic weight percent to about 50 atomic weight percent silicon, from about 15 atomic weight percent to about 30 atomic weight percent oxygen, from about 15 atomic weight percent to about 45 atomic weight percent carbon, and from about 8 atomic weight percent to about 30 atomic weight percent nitrogen.

5. The interconnect structure as recited in claim 1 wherein the silicon oxycarbonitride layer has a thickness ranging from about 3 nm to about 100 nm.

6. The interconnect structure as recited in claim 5 wherein the silicon oxycarbonitride layer has a thickness ranging from about 5 nm to about 50 nm.

7. The interconnect structure as recited in claim 1 wherein the silicon oxycarbonitride layer has a graded nitrogen profile.

8. The interconnect structure as recited in claim 7 wherein the graded nitrogen profile has a greater amount of nitrogen at a surface proximate the conductive feature than a surface distal the conductive feature.

9. The interconnect structure as recited in claim 1 further including an intermediate layer located between the silicon oxycarbonitride layer and the conductive feature.

10. The interconnect structure as recited in claim 1 wherein the silicon oxycarbonitride layer is a silicon oxycarbonitride hermetic layer.

11. A method for manufacturing an interconnect structure, comprising;
providing a conductive feature in or over a dielectric layer; and
forming a silicon oxycarbonitride layer over the conductive feature.

12. The method as recited in claim 11 wherein forming a silicon oxycarbonitride layer includes forming a silicon oxycarbonitride layer having at least about 2 atomic weight percent oxygen.

13. The method as recited in claim 11 wherein forming a silicon oxycarbonitride layer includes forming a silicon oxycarbonitride layer having at least about 2 atomic weight percent nitrogen.

14. The method as recited in claim 11 wherein forming a silicon oxycarbonitride layer includes forming a silicon oxycarbonitride layer having from about 30 atomic weight percent to about 50 atomic weight percent silicon, from about 15 atomic weight percent to about 30 atomic weight percent oxygen, from about 15 atomic weight percent to about 45 atomic weight percent carbon, and from about 8 atomic weight percent to about 30 atomic weight percent nitrogen.

15. The method as recited in claim 11 wherein forming a silicon oxycarbonitride layer includes forming a silicon oxycarbonitride layer using an ammonia flow rate ranging from about 100 sccm to about 2000 sccm, a helium flow rate ranging from about 100 sccm to about 2000 sccm, a trimethyl silane flow rate ranging from about 40 sccm to about 500 sccm, a carbon dioxide flow rate ranging from about 100 sccm to about 2000 sccm, a hydrogen flow rate ranging from about 100 sccm to about 2000 sccm, or any combination thereof.

16. The method as recited in claim 11 wherein forming a silicon oxycarbonitride layer includes forming a silicon oxycarbonitride layer having a thickness ranging from about 3 nm to about 100 nm.

17. The method as recited in claim 11 wherein forming a silicon oxycarbonitride layer includes forming a silicon oxycarbonitride layer having a graded nitrogen profile.

18. The method as recited in claim 17 wherein the graded nitrogen profile has a greater amount of nitrogen at a surface proximate the conductive feature than a surface distal the conductive feature.

19. The method as recited in claim 11 further including forming an intermediate layer, the intermediate layer located between the silicon oxycarbonitride layer and the conductive feature.

20. The method as recited in claim 11 wherein the silicon oxycarbonitride layer is a silicon oxycarbonitride hermetic layer.

21. An integrated circuit, comprising;
transistor devices located over a substrate;
a dielectric layer located over the transistor devices;
a conductive feature located in or over the dielectric layer; and
a silicon oxycarbonitride layer located over the conductive feature.

22. The integrated circuit as recited in claim 21 wherein the silicon oxycarbonitride layer includes at least about 2 atomic weight percent oxygen.

23. The integrated circuit as recited in claim 21 wherein the silicon oxycarbonitride layer includes at least about 2 atomic weight percent nitrogen.

24. The integrated circuit as recited in claim 21 wherein the silicon oxycarbonitride layer is a silicon oxycarbonitride hermetic layer.
